(19) United States
(12) Patent Application Publication
(10) Pub. No.: US 2024/0336834 A1
(43) Pub. Date: Oct. 10, 2024

(54) METHOD FOR PRODUCING QUANTUM DOT

(71) Applicant: NIPPON CHEMICAL INDUSTRIAL CO., LTD., Tokyo (JP)

(72) Inventors: Tomo Sakanoue, Tokyo (JP); Kazuhiro Nakatsui, Tokyo (JP)

(73) Assignee: NIPPON CHEMICAL INDUSTRIAL CO., LTD., Tokyo (JP)

(21) Appl. No.: 18/681,608

(22) PCT Filed: Aug. 19, 2022
(86) PCT No.: PCT/JP2022/031336

§ 371 Date: Feb. 6, 2024

(30) Foreign Application Priority Data
Aug. 27, 2021 (JP) 2021-138959
Aug. 8, 2022 (JP) 2022-126546

(51) Int. Cl. C09K 11/02; B82Y 20/00; B82Y 40/00; C09K 11/08; C09K 11/88

(52) U.S. Cl. CPC C09K 11/025; C09K 11/0883; C09K 11/883; B82Y 20/00; B82Y 40/00

(57) ABSTRACT

A method for producing a quantum dot having excellent in full width at half maximum (FWHM) and symmetry of the emission spectrum, the quantum dot having a core-shell structure, with a core composed of an InP-based quantum dot obtained by a reaction of at least a phosphorus source and an indium source, and a shell composed of a coating compound other than InP-based one, includes performing a reaction to coat the core with the coating compound in a solvent containing a plurality of amine derivatives. The coating compound is obtained preferably from a reaction with at least a zinc source.

### TECHNICAL FIELD

The present invention relates to a method for producing a quantum dot, particularly to a method for producing a quantum dot having a core-shell structure with a core composed of InP-based quantum dot and a shell composed of a coating compound other than InP-based one.

### BACKGROUND ART

In recent years, development of quantum dots as light emitting material has progressed. As typical quantum dots, cadmium-based quantum dots such as CdSe, CdTe, and CdS have been developed from the viewpoint of excellent emission characteristics, etc. However, due to high toxicity and environmental load of cadmium, a cadmium-free quantum dot is expected to be developed.

Examples of the cadmium-free quantum dot include an InP (indium phosphide)-based quantum dot. An InP-based quantum dot is inferior to a Cd-based quantum dot in terms of the quantum yield and the full width at half maximum of emission peak (hereinafter also referred to as FWHM), so that various improvement methods have been proposed. For example, a disclosed method in Patent Literature 1 includes mixing oleylamine and zinc acetate with an InP quantum dot serving as core to form a Zn-based shell. A disclosed method in Patent Literature 2 includes mixing an InP quantum dot with zinc chloride and oleylamine, and then adding an Se source and an S source to form an Se/S-based shell. Further, according to Non-Patent Literature 1, zinc chloride and 1-dodecanethiol are used to form a ZnS shell on an InP quantum dot core.

### CITATION LIST

### Patent Literature

Patent Literature 1
U.S. Patent Application Publication No. 2020-0362241 Patent Literature 2
China Patent Application Publication No. 108641720

### Non Patent Literature

Non Patent Literature 1
Halide-Amine Co-Passivated Indium Phosphide Colloidal Quantum Dots in Tetrahedral Shape, Angewandte Chemie, International Edition (2016), 55, 3714-3718

### SUMMARY OF INVENTION

### Technical Problem

However, although the InP-based quantum dots obtained by the above-described conventional production methods exhibit excellent properties in terms of FWHM and quantum yield, in order to achieve performance equivalent to that of Cd-based quantum dots, improvement in the symmetry of emission spectrum and further improvement in FWHM are required. Regarding the symmetry of emission spectrum, the more bilaterally symmetrical the spectral shapes on the short wavelength side and the long wavelength side about the emission peak wavelength, the more the color purity of the emitted light is improved. In order to improve the symmetry of emission spectrum, it is necessary to suppress the generation of spectra with a gentle slope appearing on the short wavelength side and the long wavelength side farther from the emission peak wavelength (tails), and a spectrum having an inflection point appearing in the emission peak (shoulder).

It is believed that defects on the surface of the InP-based quantum dot that serves as core are the cause of generation of the tail. It is also believed that generation of the shoulder is caused because a ligand used for surface treatment strongly binds to a specific crystal plane of the quantum dot to inhibit shell formation, so that rapid and uniform shell formation is not performed, resulting in variations in quantum dot size.

### Solution to Problem

As a result of extensive study for solving the above problem, the present inventors have found that defects on the surface of an InP-based quantum dot that serves as core can be effectively blocked by performing shell formation in a solvent containing multiple types of amine derivatives, so that the FWHM and symmetry of emission spectrum can be improved at the same time. The present invention has been thus completed.

In other words, the present invention is a method for producing a quantum dot having a core-shell structure, with a core composed of an InP-based quantum dot obtained by a reaction of at least a phosphorus source and an indium source, and a shell composed of a coating compound other than InP-based one, the method including
performing a reaction to coat the core with the coating compound in a solvent containing a plurality of amine derivatives.

### Advantageous Effects of Invention

According to the present invention, provided is a method for producing a quantum dot excellent in the FWHM and symmetry of the emission spectrum, which allows a high-quality quantum dot having high color purity to be obtained due to excellence in the FWHM and symmetry of the emission spectrum.

### BRIEF DESCRIPTION OF DRAWINGS

FIG. 1 is an emission spectrum of a quantum dot dispersion obtained in Example 1.

FIG. 2 is an emission spectrum of a quantum dot dispersion obtained in Example 2.

FIG. 3 is an emission spectrum of a quantum dot dispersion obtained in Example 3.

FIG. 4 is an emission spectrum of a quantum dot dispersion obtained in Example 4.

FIG. 5 is an emission spectrum of a quantum dot dispersion obtained in Example 5.

FIG. 6 is an emission spectrum of a quantum dot dispersion obtained in Comparative Example 1.

FIG. 7 is an emission spectrum of a quantum dot dispersion obtained in Comparative Example 2.

FIG. 8 is an emission spectrum of a quantum dot dispersion obtained in Comparative Example 3.

FIG. 9 is an emission spectrum of a quantum dot dispersion obtained in Comparative Example 4.

### DESCRIPTION OF EMBODIMENT

The present invention is a method for producing a quantum dot having a core-shell structure, with a core being an InP-based quantum dot obtained by a reaction of at least a phosphorus source and an indium source, which is coated with a coating compound other than InP-based one to have a shell layer, the method including performing a reaction to coat the core with the coating compound in a solvent containing a plurality of amine derivatives. Preferred embodiments of the method for producing a quantum dot of the present invention are described in the following.

### (Phosphorus Source)

As the phosphorus source for use in the production of an InP-based quantum dot that serves as core of the quantum dot in the present invention, various sources can be used according to the chemical synthesis method to be employed, including, for example, phosphine derivatives such as silylphosphine compounds and aminophosphine compounds, and phosphine gas. A silylphosphine compound represented by the following general formula (1) is preferred from the viewpoints of easy obtainability of the quantum dot, availability, and control of the particle size distribution of the resulting quantum dot. The silylphosphine compound used as phosphorus source is a tertiary compound having a phosphorus atom to which three silyl groups are bonded.

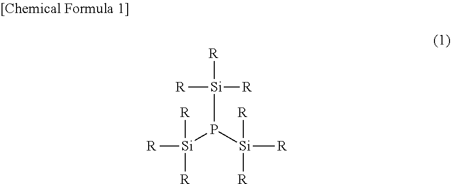

wherein R each independently are an alkyl group having 1 or more and 5 or less carbon atoms or an aryl group having 6 or more and 10 or less carbon atoms.

Preferred examples of the alkyl group having 1 or more and 5 or less carbon atoms represented by R in the general formula (1) include a straight-chain or branched-chain alkyl group, and specifically, a methyl group, an ethyl group, an n-propyl group, and an iso-propyl group, an n-butyl group, a sec-butyl group, a tert-butyl group, an iso-butyl group, an n-amyl group, an iso-amyl group, and a tert-amyl group.

Examples of the aryl group represented by R having 6 or more and 10 or less carbon atoms in the general formula (1) include a phenyl group, a tolyl group, an ethylphenyl group, a propylphenyl group, an iso-propylphenyl group, a butylphenyl group, a sec-butylphenyl group, and a tert-butylphenyl group, an iso-butylphenyl group, a methylethylphenyl group and a trimethylphenyl group.

These alkyl groups and aryl groups may have one or two or more substituents. Examples of the substituent of alkyl groups include a hydroxy group, a halogen atom, a cyano group, and an amino group, and examples of the substituent of aryl groups include an alkyl group having 1 or more and 5 or less carbon atoms, an alkoxy group having 1 or more and 5 or less carbon atoms, a hydroxy group, a halogen atom, a cyano group, and an amino group. In the case where an aryl group is substituted with an alkyl group or an alkoxy group, the number of carbon atoms in the aryl group includes the number of carbon atoms of the alkyl group or the alkoxy group.

The plurality of R in the above general formula (1) may be the same or different. Further, the three silyl groups (—SiR₃) present in the above general formula (1) may be the same or different. As the silylphosphine compound represented by the above general formula (1), one with R being an alkyl group having 1 or more and 4 or less carbon atoms or a phenyl group unsubstituted or substituted with an alkyl group having 1 or more and 4 or less carbon atoms is preferred, from the viewpoint of a phosphorus source having excellent reactivity with other molecules such as an indium source during a synthesis reaction; and a trimethylsilyl group is particularly preferred.

### (Indium Source)

As the indium source used in producing the InP quantum dot, various sources may be used in accordance with a chemical synthesis method to be employed. Preferred examples thereof include indium organic carboxylate, from the viewpoint of easily obtaining a quantum dot, and from the viewpoints of easy availability and easy control of the particle size distribution of the resulting quantum dot. For example, an indium saturated aliphatic carboxylate such as indium acetate, indium formate, indium propionate, indium butyrate, indium valerate, indium caprylate, indium enanthate, indium caprylate, indium pelargonate, indium caprate, indium laurate, indium myristate, indium palmitate, indium margarate, indium stearate, indium oleate, indium 2-ethylhexanate; and an indium unsaturated aliphatic carboxylate such as indium oleate and indium linoleate may be preferably used. In particular, from the viewpoints of availability and particle size distribution control, it is preferable to use at least one selected from the group consisting of indium acetate, indium laurate, indium myristate, indium palmitate, indium stearate, and indium oleate. In particular, an indium salt of a higher carboxylic acid having 12 or more and 18 or less carbon atoms is preferred.

### (Reaction Between Phosphorus Source and Indium Source)

Examples of the chemical synthesis method of the InP quantum dot include a sol-gel method (colloid method), a hot soap method, an inverse micelle method, a solvothermal method, a molecular precursor method, a hydrothermal synthesis method, and a flux method. In the present invention, it is preferable that a phosphorus source and an indium source be mixed and reacted at a temperature of 20° C. or more and 150° C. or less to obtain an InP quantum dot precursor, followed by a reaction at a temperature of 200° C. or more and 350° C. or less to obtain an InP-based quantum dot.

### (Production Method of InP Quantum Dot Precursor)

An InP quantum dot precursor is a cluster including subdivisions of an InP quantum dot as nanoparticle having a particle size of several nm to several tens of nm obtained through a reaction between a phosphorus source and an indium source, including a specific number of constituent atoms, for example, several to several hundreds of atoms, with excellent stability in a solvent. The InP quantum dot precursor may be a magic size cluster composed of several tens to several hundreds of atoms, or may have a smaller number of atoms than that. Since the InP quantum dot precursor can have excellent stability in a solvent as described above, there is an advantage that a quantum dot having a narrow particle size distribution is easily obtained therefrom. In the present specification, InP in the InP quantum dot precursor means including In and P, though the molar ratio between In and P may not be 1:1. An InP quantum dot precursor usually includes In and P, and a ligand derived from a phosphorus source or an indium source as a raw material may be bonded to an In or P atom located in the outermost shell thereof. Examples of the ligand include an organic carboxylic acid residue in the case where the indium source is an indium salt of the organic carboxylic acid, and an alkylphosphine used as an additive.

The molar ratio between the phosphorus source and the indium source to be mixed during the reaction, i.e., P: In, is preferably 1:0.5 or more and 10 or less, more preferably 1:1 or more and 5 or less, from the viewpoint of successfully obtaining an InP quantum dot precursor.

It is preferable that the reaction between the phosphorus source and the indium source be performed in an organic solvent from the viewpoints of reactivity and stability. Examples of the organic solvent include a non-polar solvent from the viewpoint of stability of the phosphorus source and the indium source, and preferred examples thereof include solvents such as an aliphatic hydrocarbon, an unsaturated aliphatic hydrocarbon, an aromatic hydrocarbons, trialkylphosphine, and trialkylphosphine oxide from the viewpoints of reactivity and stability. Examples of the aliphatic hydrocarbon include n-hexane, n-heptane, n-octane, n-nonane, n-decane, n-dodecane, n-hexadecane, and n-octadecane. Examples of the unsaturated aliphatic hydrocarbon include 1-undecene, 1-dodecene, 1-tetradecene, 1-hexadecene, and 1-octadecene. Examples of the aromatic hydrocarbon include benzene, toluene, xylene, and styrene. Examples of the trialkylphosphine include triethylphosphine, tributylphosphine, tridecylphosphine, trihexylphosphine, trioctylphosphine, and tridodecylphosphine. Examples of the trialkylphosphine oxide include triethylphosphine oxide, tributylphosphine oxide, tridecylphosphine oxide, trihexylphosphine oxide, trioctylphosphine oxide, and tridodecylphosphine oxide.

It is preferable that the solvent be dehydrated before use from the viewpoint of preventing decomposition of the phosphorus source and the indium source and the resulting formation of impurities. The water content in the solvent is preferably 20 ppm or less based on mass. It is also preferable to degas the solvent before use to remove oxygen. Degassing may be done by any method such as reducing pressure and substitution with an inert atmosphere in a reaction vessel.

The concentrations of the phosphorus source and the indium source in the reaction solution obtained by mixing the phosphorus source and the indium source, as the phosphorus atom based concentration and the indium atom based concentration, respectively, relative to 100 g of the reaction solution are, for example, preferably in the range of 0.1 mmol or more and 10 mmol or less, more preferably in the range of 0.1 mmol or more and 3 mmol or more, from the viewpoints of reactivity and stability.

A preferred method of mixing a phosphorus source and a indium source includes dissolving the phosphorus source and the indium source in organic solvents, respectively, and mixing the solution in which the phosphorus source is dissolved and the solution in which the indium source is dissolved, from the viewpoint of easy generation of an InP quantum dot precursor. The solvent for dissolving the phosphorus source and the solvent for dissolving the indium source may be the same or different.

In this case, the phosphorus atom based concentration of the phosphorus source in the solution in which the phosphorus source is dissolved in an organic solvent is preferably in the range of 20 mmol/L or more and 2000 mmol/L or less, more preferably in the range of 80 mmol/L or more and 750 mmol or less, from the viewpoint of reactivity and stability. Also, the indium atom based concentration of the indium source in the solution in which the indium source is dissolved in an organic solvent is preferably in the range of 0.1 mmol/L or more and 20 mmol/L or less, more preferably 0.2 mmol/L or more and 10 mmol/L or less, from the viewpoint of reactivity and stability.

It is preferable to add an additive that can serve as a ligand to the reaction solution containing the phosphorus source and the indium source, from the viewpoint of improving the quality of the resulting InP quantum dot precursor and InP-based quantum dot. The present inventors believe that the coordination of an additive that can serve as a ligand to In or the change in polarity of the reaction field affects the quality of an InP quantum dot precursor and an InP-based quantum dot. Examples of the additive include a phosphine derivative, an amine derivative, and a phosphonic acid.

As the phosphine derivative, a primary or higher and tertiary or lower alkyl phosphine is preferred, and preferred examples thereof include one having a straight chain alkyl group having 2 or more and 18 or less carbon atoms in the molecule. The alkyl groups in the molecule may be the same or different. Specific examples of the straight chain alkylphosphine having an alkyl group having 2 or more and 18 or less carbon atoms include monoethylphosphine, monobutylphosphine, monodecylphosphine, monohexylphosphine, monooctylphosphine, and monododecylphosphine, monohexadecylphosphine, diethylphosphine, dibutylphosphine, didecylphosphine, dihexylphosphine, dioctylphosphine, didodecylphosphine, dihexadecylphosphine, triethylphosphine, tributylphosphine, tridecylphosphine, trihexylphosphine, trioctylphosphine, tridodecylphosphine, and trihexadecylphosphine. Among them, from the viewpoint of improving the quality of the resulting InP quantum dot precursor and InP-based quantum dot, those having an alkyl group having 4 or more and 12 or less carbon atoms in the molecule are particularly preferred. A trialkylphosphine is preferred, and trioctylphosphine is most preferred.

It is preferable that the amine derivative be a primary or higher and tertiary or lower alkylamine, and preferred examples thereof include a straight-chain or branched-chain alkyl amine with an alkyl group having 2 or more and 18 or less carbon atoms in the molecule, and an aromatic alkyl amine having 6 or more and 12 or less carbon atoms. The alkyl groups in the molecule may be the same or different. Specific examples of the alkylamine having a straight chain alkyl group having 2 or more and 18 or less carbon atoms include monoethylamine, monobutylamine, monodecylamine, monohexylamine, monooctylamine, monododecylamine, monohexadecylamine, diethylamine, dibutylamine, didecylamine, dihexylamine, dioctylamine, didodecylamine, dihexadecylamine, triethylamine, tributylamine, tridecylamine, trihexylamine, trioctylamine, tridodecylamine, and trihexadecylamine. Examples of the branched-chain alkylamine with an alkyl group having 2 or more and 18 or less carbon atoms include isopropylamine, isobutylamine, 1-methylbutylamine, 1-ethylpropylamine, 2-ethylbutylamine, 2-ethylhexylamine, di-isopropylamine, di-isobutylamine, di-1-methylbutylamine, di-1-ethylpropylamine, di-2-ethylbutylamine, di-2-ethylhexylamine, tri-isopropylamine, tri-isobutylamine, tri-1-methylbutylamine, tri-1-ethylpropylamine, and tri-2-ethylbutylamine. Specific examples of the aromatic alkylamines with an alkyl groups having 6 or more and 12 or less carbon atoms include aniline, diphenylamine, triphenylamine, monobenzylamine, dibenzylamine, tribenzylamine, naphthylamine, dinaphthylamine, and trinaphthylamine. It is also preferable that the phosphonic acid be a monoalkylphosphonic acid having a straight chain alkyl group having 2 or more and 18 or less carbon atoms in the molecule.

It is preferable that the amount of the additive that can serve as a ligand in the reaction solution containing a phosphorus source and an indium source be 0.2 mol or more relative to 1 mol of In, from the viewpoint of enhancing the effect for improving the quality of the InP quantum dot precursor and the InP-based quantum dot through addition of the additive that can serve as a ligand. It is preferable that the amount added of the additive that can serve as a ligand be 20 mol or less relative to 1 mol of In from the viewpoint of the effect for improving quality. From these viewpoints, it is more preferable that the amount added of the additive that can serve as a ligand be 0.5 mol or more and 15 mol or less relative to 1 mol of In.

The timing of addition of the additive that can serve as a ligand to the reaction solution may be as follows. The additive that can serve as a ligand is mixed with an indium source to form a mixed solution, and the mixed solution may be mixed with a phosphorus source. Alternatively, the additive that can serve as a ligand is mixed with a phosphorus source to form a mixed solution, and this mixed solution may be mixed with an indium source. Alternatively, the additive that can serve as a ligand may be mixed with a mixed solution of a phosphorus source and an indium source.

The solution in which a phosphorus source is dissolved in an organic solvent and the solution in which an indium source is dissolved in an organic solvent may be preliminarily heated to a preferred reaction temperature described later or to a lower or higher temperature than that before mixing, or may be heated to a preferred reaction temperature described later after mixing. The preliminary heating temperature is preferably within ±10° C. of the reaction temperature and at 20° C. or more, and more preferably within ±5° C. of the reaction temperature and at 30° C. or more, from the viewpoints of reactivity and stability.

From the viewpoints of reactivity and stability, the reaction temperature between a phosphorus source and an indium source is preferably 20° C. or more and 150° C. or less, more preferably 40° C. or more and 120° C. or less. From the viewpoints of reactivity and stability, the reaction time at the reaction temperature is preferably 0.5 minutes or more and 180 minutes or less, more preferably 1 minute or more and 80 minutes or less.

Through the above steps, a reaction solution containing an InP quantum dot precursor is obtained.

The formation of an InP quantum dot precursor in the reaction solution can be confirmed, for example, through measurement of the ultraviolet-visible light absorption spectrum (UV-VIS spectrum). In the case where an InP quantum dot precursor is formed in a reaction solution obtained by reacting an In source and a P source, a peak or a shoulder is observed in the range of 300 nm or more and 460 nm or less in a UV-VIS spectrum. A shoulder clearly has an inflection point, though not having a sharp tip shape as clearly as a peak. In the case where a shoulder is observed, it is preferable to have one or two or more inflection points in the range of 300 nm or more and 460 nm or less, particularly 310 nm or more and 420 nm or less. It is preferable that the UV-VIS spectrum be measured at 0° C. or more and 40° C. or less. A sample solution is prepared by diluting the reaction solution with a solvent such as hexane. Each of the amounts of In and P in the sample solution in measurement is preferably in the range of 0.01 mmol or more and 1 mmol or less, more preferably 0.02 mmol or more and 0.3 mmol or less in terms of phosphorus atoms and indium atoms, respectively, relative to 100 g of the sample solution. Examples of the solvent of the reaction solution include solvents that can be suitably used for the reaction of the indium source and the phosphorus source, which will be described later. As described later, the InP quantum dot precursor in the solvent heated to 200° C. or more and 350° C. or less grows into an InP quantum dot, and a peak is observed in the UV-VIS spectrum of the reaction solution usually in the range of 450 nm or more and 550 nm or less. In contrast, in the reaction solution before heating, no peak is observed in the range of 450 nm or more and 550 nm or less.

Further, it can be confirmed that an InP quantum dot precursor is produced in the reaction solution by, for example, color change of the reaction solution into yellowish green to yellow, instead of by the UV-VIS spectrum. The color may be visually confirmed. For example, a reaction solution containing an InP magic size cluster is usually yellow, and a reaction solution containing a precursor composed of In and P and having a smaller number of atoms than the magic size cluster is usually yellowish green.

### (Method for Producing InP-Based Quantum Dot)

The InP-based quantum dot refers to a semiconductor nanoparticle containing at least In and P, having a quantum confinement effect. The quantum confinement effect means that electrons in a substance having about the size of Bohr radius cannot move freely, and the electron energy in such a state is not arbitrary but can take only a specific value. The particle size of a quantum dot (semiconductor nanoparticle) is usually in the range of several nm to several tens of nm. However, among those corresponding to the description of quantum dots, those corresponding to quantum dot precursors are not included in the category of quantum dots in the present invention.

The reaction solution containing the InP quantum dot precursor is at a temperature of preferably 20° C. or more and 150° C. or less, more preferably 40° C. or more and 120° C. or less, after completion of the reaction, and may be used at the temperature maintained or cooled to room temperature.

The reaction solution containing the InP quantum dot precursor may be directly heated or mixed with a heated solvent to obtain an InP-based quantum dot. In the case of directly heating the reaction solution containing the InP quantum dot precursor, from the viewpoint of particle size control, the reaction solution is heated at a temperature of preferably 200° C. or more and 350° C. or less, more preferably 240° C. or more and 330° C. or less to obtain the InP-based quantum dot. The rate of temperature rise during heating is preferably 1° C./min or more and 50° C./min or less, more preferably 2° C./min or more and 40° C./min or less from the viewpoints of time efficiency and particle size control. Further, from the viewpoint of particle size control, the heating time at the temperature is preferably 0.5 minutes or more and 180 minutes or less, and more preferably 1 minute or more and 60 minutes or less.

In the case of mixing the reaction solution containing the InP quantum dot precursor with a heated solvent, or in the case of obtaining an InP-based quantum dot by a so-called hot injection method, the reaction solution containing the InP quantum dot precursor may be rapidly added to an organic solvent heated preferably at a temperature of 200° C. or more and 350° C. or less, more preferably at 240° C. or more and 330° C. or less, to obtain an InP-based quantum dot, from the viewpoint of particle size control. As the organic solvent, the same organic solvent as used in the reaction between the phosphorus source and the indium source may be used. Mixing of the reaction solution containing the InP quantum dot precursor and the organic solvent is performed at a holding temperature of 200° C. or more and 350° C. or less, more preferably at 240° C. or more and 330° C. or less, for 10 minutes or less, preferably for 0.1 minutes or more and 8 minutes or less, from the viewpoint of particle size control.

The stability of the InP quantum dot precursor in a solvent is thermodynamic, and the InP quantum dot precursor has a property reactive to heating. For example, an InP quantum dot precursor in the solvent can grow into an InP quantum dot by heating to preferably 200° C. or more and 350° C. or less, more preferably 240° C. or more and 330° C. or less. This can be confirmed by observation of a peak shift toward the long wavelength side in measurement of UV-VIS spectrum of the reaction solution after heating. For example, in the case where an InP quantum dot precursor in a solvent is heated to preferably 200° C. or more and 350° C. or less, more preferably 240° C. or more and 330° C. or less, without addition of elements other than In and P constituting the quantum dot, a peak is observed in the range of 420 nm or more and 590 nm or less in the UV-VIS spectrum. InP in the InP quantum dot means including In and P, though the molar ratio between In and P may not be 1:1. In the UV-VIS spectrum in the range of 300 nm or more and 800 nm or less of a liquid containing an InP quantum dot obtained by heating an InP quantum dot precursor to preferably 200° C. or more and 350° C. or less, more preferably 240° C. or more and 330° C. or less, it is preferable that an absorption peak having a highest peak height be observed in the range of 420 nm or more and 600 nm or less, depending on the InP quantum dot to obtain an intended color.

It can also be confirmed that an InP quantum dot is produced in a reaction solution by, for example, color change of the reaction solution into yellow to red. The color may be visually confirmed.

The UV-VIS spectrum of the reaction solution and the color of the reaction solution after heating of an InP quantum dot precursor described above typically refer to the cases where heating is performed without addition of elements other than In and P constituting the quantum dot. However, as described above, the present invention does not exclude the case where heating is performed with addition of such a compound to an InP quantum dot precursor.

In the present invention, a quantum dot containing In and P but containing no other constituent elements, and a quantum dot containing In and P and a further constituent element are collectively referred to as “InP-based quantum dot”.

Since the resulting InP-based quantum dot contains by-products and unreacted impurities in the reaction solution, purification treatment may be performed before performing the surface treatment described below. In the purification treatment, an organic solvent such as ethanol, methanol, 2-propanol, acetone, and acetonitrile is added to the reaction solution containing the InP-based quantum dot to precipitate the InP-based quantum dot. After separation into the solution containing impurities and the InP-based quantum dot, the separated InP-based quantum dot is dispersed in an organic solvent such as toluene and hexane. The separation of the solution containing impurities from the InP-based quantum dot may be performed by an operation such as centrifugation, decantation, and suction filtration.

The InP-based quantum dot produced by the production method of the present invention may be a quantum dot composed of a composite compound having an element M other than phosphorus and indium in addition to In and P (also referred to as a composite quantum dot of In, P and M). It is preferable that the element M be at least one selected from the group consisting of Be, Mg, Ca, Mn, Cu, Zn, Cd, B, Al, Ga, N, As, Sb, and Bi from the viewpoint of improving the quantum yield. Typical examples of the InP-based quantum dot containing element M include InGaP, InZnP, InAlP, InGaAlP, InNP, InAsP, InPSb, and InPBi. In order to obtain an InP-based quantum dot containing element M, a liquid containing a compound containing element M may be added to the reaction solution when the liquid containing the InP quantum dot precursor is heated, or a liquid containing the InP quantum dot precursor may be added to the reaction solution when the liquid containing a compound containing element M is heated. The compound containing element M is a compound in the form of chloride, bromide or iodide of element M, or in the form of higher carboxylate having 12 or more and 18 or less carbon atoms, in the case where element M is Be, Mg, Ca, Mn, Cu, Zn, Cd, B, Al and Ga. In the case where the compound is in the form of higher carboxylate, the carboxylic acid may be the same as or different from the carboxylic acid of the indium carboxylate used in the reaction. In the case where element M is N, As, Sb, and Bi, a compound in a form with element M to which three silyl groups or amino groups are bonded may be suitably used.

The surface of the InP-based quantum dot of the present invention may be treated with a surface treatment agent for the purpose of increasing the quantum yield. The surface treatment of the surface of an InP-based quantum dot protects the defects in the surface of the InP-based quantum dot, so that the quantum yield can be improved. Through performing the shell formation described below consecutively to the surface treatment, the FWHM and symmetry of the emission spectrum of the resulting quantum dot can be also improved. Examples of the suitable surface treatment agent include a metal-containing compound such as a metal carboxylate, a metal carbamate, a metal halide, a metal thiocarboxylate, a metal acetylacetonate and hydrates thereof, a halogen-containing compound such as a halogenated alkanoyl compound, a halogenated quaternary ammonium compound, a halogenated quaternary phosphonium compound, a halogenated aryl compound and a halogenated tertiary hydrocarbon compound, and an organic acid such as a carboxylic acid, a carbamic acid, a thiocarboxylic acid, a phosphonic acid and a sulfonic acid. Among these, metal carboxylates, metal carbamates, and metal halides are preferred from the viewpoint of further improving the quantum yield.

The metal carboxylate may have a straight chain, branched chain or cyclic alkyl group having 1 or more and 24 or less carbon atoms, containing an saturated or unsaturated bond, which may be unsubstituted or substituted with a halogen atom, or may have a plurality of carboxylic acids in the molecule. Examples of the metal of the metal carboxylate include Li, Na, K, Rb, Cs, Be, Mg, Ca, Sr, Ba, Sc, Y, Ti, Zr, V, Nb, Cr, Mo, Mn, Fe, Co, Ni, Cu, Ag, Zn, Cd, Hg, B, Al, Ga, In, Tl, Ge, Sn, Pb, Sb, Bi, La, Ce and Sm. Among these, the metal of the metal carboxylate is preferably Zn, Cd, Al and Ga, and more preferably Zn, from the viewpoint of further protecting defects in the surface of an InP-based quantum dot. Examples of the metal carboxylates include zinc acetate, zinc trifluoroacetate, zinc myristate, zinc oleate, and zinc benzoate.

For the metal carbamate, among the metals described above, Zn, Cd, Al and Ga are preferred, and Zn is more preferred from the viewpoint of further protecting defects in the surface of an InP-based quantum dot. Specific examples thereof include zinc dimethyldithiocarbamate, zinc diethyldithiocarbamate, zinc dibutyldithiocarbamate and zinc N-ethyl-N-phenyldithiocarbamate.

As the metal halide, among the metals described above, Zn, Cd, Al and Ga are preferred, and Zn is more preferred from the viewpoint of further protecting defects in the surface of an InP-based quantum dot. Specific examples thereof include zinc fluoride, zinc chloride, zinc bromide and zinc iodide.

As the method for surface-treating an InP-based quantum dot, for example, a surface treatment agent may be added to the reaction solution containing the InP-based quantum dot described above. The temperature at which the surface treatment agent is added to the reaction solution containing the InP-based quantum dot is preferably 0° C. or more and 350° C. or less, more preferably 20° C. or more and 250° C. or less, from the viewpoints of controlling particle size and improving the quantum yield. The treatment time is preferably 1 minute or more and 600 minutes or less, and more preferably 5 minutes or more and 240 minutes or less. The amount of the surface treatment agent added depends on the type of the surface treatment agent, being preferably 0.001 g/L or more and 1000 g/L or less, more preferably 0.1 g/L or more and 500 g/L or less, relative to the reaction solution containing the InP-based quantum dot.

Examples of the method for adding the surface treatment agent include a method of directly adding the surface treatment agent to the reaction solution, and a method of adding the surface treatment agent dissolved or dispersed in a solvent to the reaction solution. In the method of adding the surface treatment agent dissolved or dispersed in a solvent to the reaction solution, examples of the solvent for use include acetonitrile, propionitrile, isovaleronitrile, benzonitrile, acetone, methyl ethyl ketone, methyl isobutyl ketone, acetyl acetone, acetophenone, dimethylsulfoxide, dimethylformamide, dimethylacetamide, methanol, ethanol, isopropanol, cyclohexanol, phenol, methyl acetate, ethyl acetate, isopropyl acetate, phenyl acetate, tetrahydrofuran, 2-methyltetrahydrofuran, tetrahydropyran, diethyl ether, t-butyl methyl ether, cyclohexyl methyl ether, anisole, diphenyl ether, hexane, cyclohexane, benzene, toluene, 1-decene, 1-octadecene, triethylamine, tri-n-octylamine, oleylamine, dioctylamine, dibenzylamine, di-2-ethylhexylamine, and water.

### (Production of Quantum Dot Having Core-Shell Structure)

The quantum dot obtained by the production method of the present invention has a core-shell structure with a core being the InP-based quantum dot, which is covered with a coating compound. On the core surface, a second inorganic material having a wider bandgap than the core is grown (shell layer) to protect defects on the core surface, etc., so that nonradiative deactivation due to charge recombination is suppressed and the quantum yield and the stability can be improved. Examples of the suitable coating compound include ZnS, ZnSe, ZnSeS, ZnTe, ZnSeTe, ZnTeS, ZnO, ZnOS, ZnSeO, ZnTeO, GaP, and GaN. In the present invention, the coating compound is preferably obtained by reaction with at least a zinc source.

In the case of producing a quantum dot having a core-shell structure with a core being an InP-based quantum dot, which is covered with a coating compound, it is preferable that surface treatment and shell formation of the InP-based quantum dot as core be performed continuously from the viewpoint of improving the FWHM and symmetry of the emission spectrum. As the surface treatment agent used in the surface treatment, the same one as the surface treatment agent for InP-based quantum dot described above may be used. In performing surface treatment and shell formation continuously, the InP-based quantum dot as core is simultaneously present with the surface treatment agent and the coating compound raw material in a reaction solution, so that after performing the surface treatment of the InP-based dot as core at a predetermined temperature, the reaction solution is subsequently heated to form a shell of the coating compound.

In the case of producing a quantum dot having a core-shell structure with a core being an InP-based quantum dot, which is coated with a coating compound, examples of the method of forming the coating include mixing a reaction solution containing a surface-treated InP-based quantum dot and a coating compound raw material, or mixing a reaction solution containing an InP-based quantum dot, a coating compound raw material and a surface treatment agent, and causing a reaction at a temperature of 200° C. or more and 350° C. or less. Alternatively, a part of the coating compound raw material (for example, a metal source such as Zn) is heated to the same temperature, and added to and mixed with a reaction solution containing the InP-based quantum dot before the addition of the other coating compound raw material. The mixture is then heated to 20° C. or more and 350° C. or less, further 200° C. or more and 330° C. or less, and the remaining coating compound raw material may be added thereto to cause a reaction. The timing of mixing the metal source such as Zn with the reaction solution containing the InP-based quantum dot is not limited to before the addition of the other coating compound raw material, and may be after the addition.

As metal source for Zn and the like, which is the coating compound raw material, a halide or organic carboxylate thereof is preferably used. Examples of the metal halide as zinc source include zinc fluoride, zinc chloride, zinc bromide, and zinc iodide. As the metal organic carboxylate, a long-chain fatty acid salt having 12 or more and 18 or less carbon atoms is particularly preferred in terms of particle size control, particle size distribution control, and quantum yield improvement. Among these metal sources, a metal halide is preferred, zinc fluoride, zinc chloride, zinc bromide or zinc iodide is more preferred, and zinc chloride is particularly preferred, from the viewpoint of excellent affinity with an amine derivative described below. The purpose of the present invention is to obtain a quantum dot with excellent FWHM and symmetry of the emission spectrum. The inventors believe that a combination of a metal halide and an amine derivative allows the solubility of the metal halide into the amine derivative as solvent to increase due to excellent affinity therebetween, so that the effect of protecting defects existing on the surface of the InP-based quantum dot as core increases to suppress the generation of the spectra with a gentle slope on the short wavelength side and the long wavelength side farther away from the emission peak wavelength (tails).

Preferred examples of the sulfur source include a straight or branched long-chain alkanethiol having 8 or more and 18 or less carbon atoms such as dodecanethiol, and a trialkylphosphine sulfide compound having 4 or more and 12 or less carbon atoms such as and trioctylphosphine sulfide. Preferred examples of the selenium source include a trialkylphosphine selenide compound having 4 or more and 12 or less carbon atoms such as trioctylphosphine selenide. Preferred examples of the tellurium source include a trialkylphosphine telluride compound having 4 or more and 12 or less carbon atoms such as trioctylphosphine telluride.

In the method for producing a quantum dot of the present invention, the reaction between the InP-based quantum dot and the coating compound raw material, or the reaction among the InP-based quantum dot, the coating compound raw material, and the surface treatment agent is performed in a solvent containing a plurality of amine derivatives. Alternatively, a mixture of plural types of amine derivatives may also be used as solvent. The reaction solution for the reaction is preferably prepared by mixing the coating compound raw material and the solvent, or mixing the coating compound raw material, the surface treatment agent and the solvent in advance, and then mixing with the InP-based quantum dot. The present inventors believe that through such a treatment, a uniform reaction field is provided to obtain a core-shell type quantum dot with a uniform size during shell formation, so that the generation of the spectrum having an inflection point in the emission peak (shoulder) can be suppressed.

Examples of the amine derivatives include caprylamine, laurylamine, stearylamine, oleylamine, monoethylamine, monobutylamine, monodecylamine, monohexylamine, monooctylamine, monododecylamine, monohexadecylamine, benzylamine, diethylamine, dibutylamine, didecylamine, dihexylamine, dioctylamine, didodecylamine, dihexadecylamine, dibenzylamine, di-2-ethylhexylamine, triethylamine, tributylamine, tridecylamine, trihexylamine, trioctylamine, tridodecylamine, trihexadecylamine, and tribenzylamine. By using at least two or more of these amine derivatives in combination, the resulting quantum dot has excellent symmetry of the emission spectrum. From the viewpoint of preventing generation of the shoulder on the short wavelength side and the tail on the long wavelength side of the emission spectrum, use of a combination of a primary amine derivative and a secondary or tertiary amine derivative is preferred. In particular, a combination of one or more selected from oleylamine, monooctylamine, and monohexadecylamine, and one or more selected from dioctylamine, trioctylamine, di-2-ethylhexylamine, and dibenzylamine is preferred, and a combination of oleylamine and dioctylamine, dibenzylamine or di-2-ethylhexylamine is more preferred.

The amount of the amine derivative used depends on the types of the coating compound raw material and the amine derivative used, and the mass ratio, i.e., (Coating compound raw material):(Amine derivative), is preferably 1:0.5 or more and 1:100 or less, more preferably 1:1 or more and 1:10 or less.

In the case of using a metal such as zinc as the coating compound, for example, the amount of the coating compound raw material used is preferably 0.5 mol or more and 100 mol or less, and more preferably 4 mol or more and 50 mol or less, relative to 1 mol of indium in a reaction solution containing the InP-based quantum dot. The preferred amount of the sulfur source or selenium source used corresponds to the amount of metal described above.

The amount of the surface treatment agent used depends on the type of the surface treatment agent, being preferably 0.001 g/L or more and 1000 g/L or less, more preferably 0.1 g/L or more and 500 g/L or less, relative to the reaction solution containing the InP-based quantum dot.

In the present invention, for the purpose of increasing the quantum yield, the surface of the core-shell type quantum dot may be treated with a surface treatment agent or the like as in the surface treatment of the InP-based quantum dot. Through the surface treatment of the surface of the core-shell type quantum dot, defects in the surface of the shell layer can be protected, so that the quantum yield can be improved. Examples of the suitable surface treatment agent include a metal-containing compound such as a metal carboxylate, a metal carbamates, a metal thiocarboxylate, a metal halide, a metal acetylacetonate and hydrates thereof, and a halogen-containing compound such as a halogenated alkanoyl compound, a halogenated quaternary ammonium compound, a halogenated quaternary phosphonium compound, a halogenated aryl compound, and a halogenated tertiary hydrocarbon compound. Among these, a metal carboxylate or a metal carbamate is preferred from the viewpoint of further improving the quantum yield.

The metal carboxylate may have a straight chain, branched chain or cyclic alkyl group having 1 or more and 24 or less carbon atoms, containing an saturated or unsaturated bond, which may be unsubstituted or substituted with a halogen atom, or may have a plurality of carboxylic acids in the molecule. Examples of the metal of the metal carboxylate include Li, Na, K, Rb, Cs, Be, Mg, Ca, Sr, Ba, Sc, Y, Ti, Zr, V, Nb, Cr, Mo, Mn, Fe, Co, Ni, Cu, Ag, Zn, Cd, Hg, B, Al, Ga, In, TI, Ge, Sn, Pb, Sb, Bi, La, Ce and Sm. Among these, the metal of the metal carboxylate is preferably Zn, Cd, Al and Ga, and more preferably Zn, from the viewpoint of further protecting defects in the surface of a core-shell type quantum dot. Examples of the metal carboxylates include zinc acetate, zinc trifluoroacetate, zinc myristate, zinc oleate, and zinc benzoate.

As the metal carbamate, among the metals described above, Zn, Cd, Al and Ga are preferred, and Zn is more preferred from the viewpoint of further protecting defects in the surface of a core-shell type quantum dot. Specific examples thereof include zinc dimethyldithiocarbamate, zinc diethyldithiocarbamate, zinc dibutyldithiocarbamate and zinc N-ethyl-N-phenyldithiocarbamate.

As the method for surface-treating the shell layer, for example, a surface treatment agent may be added to the reaction solution containing the core-shell type quantum dot. The temperature at which the surface treatment agent is added to the reaction solution containing the core-shell type quantum dot is preferably 0° C. or more and 350° C. or less, more preferably 20° C. or more and 300° C. or less, from the viewpoints of controlling particle size and improving the quantum yield. The treatment time is preferably 1 minute or more and 600 minutes or less, and more preferably 5 minutes or more and 240 minutes or less. The amount of the surface treatment agent added depends on the type of the surface treatment agent, being preferably 0.01 g/L or more and 1000 g/L or less, more preferably 0.1 g/L or more and 100 g/L or less, relative to the reaction solution containing the core-shell type quantum dot.

Examples of the method for adding the surface treatment agent include a method of directly adding the surface treatment agent to the reaction solution, and a method of adding the surface treatment agent dissolved or dispersed in a solvent to the reaction solution. In the method of adding the surface treatment agent dissolved or dispersed in a solvent to the reaction solution, examples of the solvent for use include acetonitrile, propionitrile, isovaleronitrile, benzonitrile, acetone, methyl ethyl ketone, methyl isobutyl ketone, acetyl acetone, acetophenone, dimethylsulfoxide, dimethylformamide, dimethylacetamide, methanol, ethanol, isopropanol, cyclohexanol, phenol, methyl acetate, ethyl acetate, isopropyl acetate, phenyl acetate, tetrahydrofuran, tetrahydropyran, diethyl ether, t-butyl methyl ether, cyclohexyl methyl ether, anisole, diphenyl ether, hexane, cyclohexane, benzene, toluene, 1-decene, 1-octadecene, triethylamine, tri-n-octylamine, and water.

Since the resulting core-shell type quantum dot contains by-products and unreacted impurities in the reaction solution, purification treatment may be performed. In the purification treatment, an organic solvent such as ethanol, methanol, 2-propanol, acetone, and acetonitrile is added to the reaction solution containing a core-shell type quantum dot to precipitate the core-shell type quantum dot. After separation into the solution containing impurities and the core-shell type quantum dot, the separated core-shell type quantum dot is dispersed in an organic solvent such as toluene and hexane. The separation of the solution containing impurities from the core-shell type quantum dot may be performed by an operation such as centrifugation, decantation, and suction filtration.

The quantum dot of the present invention obtained by the above method has high quality with excellent symmetry of the emission spectrum, being suitably used for a single electron transistor, a security ink, a quantum teleportation, a laser, a solar cell, a quantum computer, a biomarker, a light emitting diode, a display backlight, and a color filter.

### EXAMPLES

The present invention is described in more detail with reference to Examples below, though the present invention is not limited thereto. In Examples, properties were measured by the following method.
(1) Emission spectrum, maximum fluorescence wavelength, full width at half maximum (FWHM), and quantum yield (PLQY)

The resulting octane dispersion of a quantum dot was measured with an absolute PL quantum yield measurement device (Quantaurus-QY, manufactured by Hamamatsu Photonics K.K.) under measurement conditions at an excitation wavelength of 400 nm and a measurement wavelength in a range of 200 nm to 1100 nm.

### [Production Example 1] Synthesis of InP Quantum Dot Precursor

To 1.578 g of 1-octadecene, 1.275 g of indium myristate was added, and the mixture was heated to 120° C. while stirring under reduced pressure and degassed for 1.5 hours. After degassing, the pressure was returned to atmospheric pressure with nitrogen gas, and the mixture was cooled to 60° C. to obtain a 1-octadecene solution of indium myristate.

While keeping the resulting 1-octadecene solution of indium myristate at a temperature of 60° C. under nitrogen atmosphere, 2.505 g of trioctylphosphine containing 10 mass& of tris(trimethylsilyl)phosphine was added thereto. The mixture was maintained for 20 minutes, and then naturally cooled to 20° C. As a result, a yellow liquid containing an InP quantum dot precursor was obtained.

### [Production Example 2] Synthesis of InZnP Quantum Dot

To 31.56 g of 1-octadecene, 0.0832 g of zinc myristate was added, and the mixture was heated to 120° C. while stirring under reduced pressure and degassed for 1.5 hours. After degassing, the pressure was returned to atmospheric pressure with nitrogen gas, and the temperature was raised to 300° C., so that a 1-octadecene solution of zinc myristate was obtained.

While keeping the resulting 1-octadecene solution of zinc myristate at a temperature of 300° C. under nitrogen atmosphere, 5.4 g of the solution containing InP quantum dot precursor obtained in Production Example 1 was added thereto. The mixture was then maintained at 270° C. for 2 minutes, so that a brown liquid containing an InZnP quantum dot was obtained.

### Example 1

In a 10-mL reaction vessel, 0.1885 g of zinc oleate, 0.102 g of zinc chloride, 0.112 g of trioctylphosphine selenide, 0.332 g of trioctylphosphine, 0.813 g of oleylamine and 0.799 g of dioctylamine were mixed, heated to 120° C. while stirring under reduced pressure, and degassed for 30 minutes. After degassing, the pressure was returned to atmospheric pressure with nitrogen gas, and the temperature was raised to 180° C. under a nitrogen atmosphere. To the mixture, 0.925 g of the reaction solution of InZnP quantum dot obtained in Production Example 2 was added, and the mixture was held at a temperature raised to 230° C. for 30 minutes, and then held at a temperature further raised to 300° C. for 60 minutes, so that an oleylamine/dioctylamine dispersion of InZnP/ZnSe quantum dots having InZnP in the core and ZnSe in the shell was obtained. After the resulting dispersion was cooled to 240° C., 0.423 g of dodecanethiol was injected and held for 90 minutes, so that an oleylamine/dioctylamine dispersion of multishell type quantum dot having InZnP in the core with ZnSe and ZnS layered in the shell was obtained.

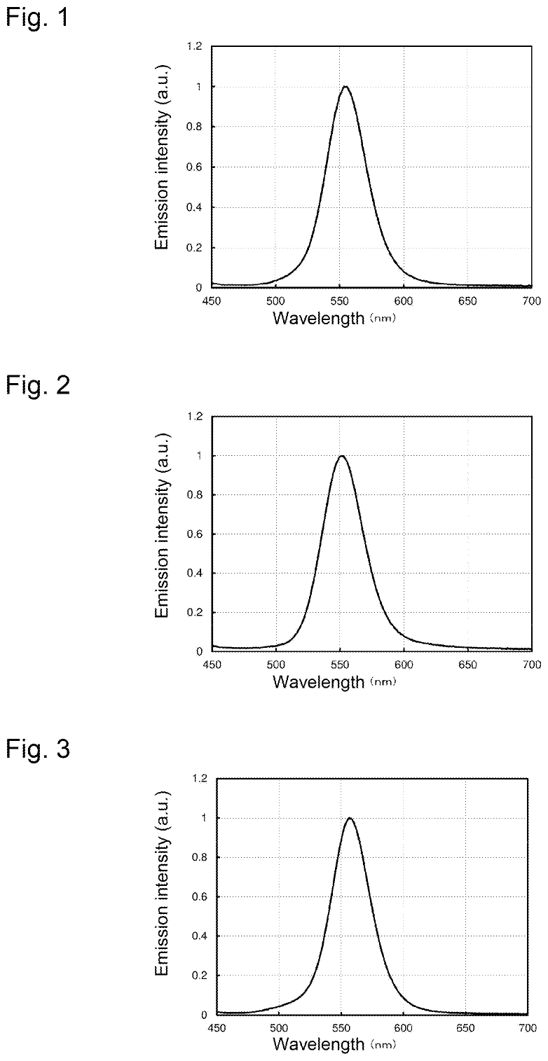

After cooling the resulting dispersion to room temperature, 15 g of acetone was added thereto and stirred, and InZnP/ZnSe/ZnS quantum dots were collected as precipitates by centrifugation. The collected InZnP/ZnSe/ZnS quantum dots were suspended in 0.866 g of toluene to obtain a toluene dispersion of InZnP/ZnSe/ZnS quantum dots. To the dispersion, 15 g of acetone was further added and stirred, and the InZnP/ZnSe/ZnS quantum dots were collected as precipitates by centrifugation. The collected InZnP/ZnSe/ZnS quantum dots were suspended in 0.7 g of octane to obtain an octane dispersion of purified InZnP/ZnSe/ZnS quantum dots. In Table 1, the measurement results of the emission properties of the resulting dispersion are shown. Further, the measurement results of emission spectrum of the resulting dispersion is shown in FIG. 1.

### Example 2

In a 10-mL reaction vessel, 0.1885 g of zinc oleate, 0.102 g of zinc chloride, 0.112 g of trioctylphosphine selenide, 0.332 g of trioctylphosphine, 0.813 g of oleylamine and 1.025 g of dibenzylamine were mixed, heated to 120° C. while stirring under reduced pressure, and degassed for 30 minutes. After degassing, the pressure was returned to atmospheric pressure with nitrogen gas, and the temperature was raised to 180° C. under a nitrogen atmosphere. To the mixture, 0.925 g of the reaction solution of InZnP quantum dot obtained in Production Example 2 was added, and the mixture was held at a temperature raised to 230° C. for 30 minutes, and then held at a temperature further raised to 300° C. for 60 minutes, so that an oleylamine/dibenzylamine dispersion of InZnP/ZnSe quantum dots having InZnP in the core and ZnSe in the shell was obtained. After the resulting dispersion was cooled to 240° C., 0.423 g of dodecanethiol was injected and held for 90 minutes, so that an oleylamine/dibenzylamine dispersion of multishell type quantum dot having InZnP in the core with ZnSe and ZnS layered in the shell was obtained.

After cooling the resulting dispersion to room temperature, 15 g of acetone was added thereto and stirred, and InZnP/ZnSe/ZnS quantum dots were collected as precipitates by centrifugation. The collected InZnP/ZnSe/ZnS quantum dots were suspended in 0.866 g of toluene to obtain a toluene dispersion of InZnP/ZnSe/ZnS quantum dots. To the dispersion, 15 g of acetone was further added and stirred, and InZnP/ZnSe/ZnS quantum dots were collected as precipitates by centrifugation. The collected InZnP/ZnSe/ZnS quantum dots were suspended in 0.7 g of octane to obtain an octane dispersion of purified InZnP/ZnSe/ZnS quantum dots. In Table 1, the measurement results of the emission properties of the resulting dispersion are shown. Further, the measurement results of emission spectrum of the resulting dispersion is shown in FIG. 2.

### Example 3

In a 10-mL reaction vessel, 0.1885 g of zinc oleate, 0.102 g of zinc chloride, 0.112 g of trioctylphosphine selenide, 0.332 g of trioctylphosphine, 0.813 g of oleylamine and 0.805 g of di-2-ethylhexylamine were mixed, heated to 120° C. while stirring under reduced pressure, and degassed for 30 minutes. After degassing, the pressure was returned to atmospheric pressure with nitrogen gas, and the temperature was raised to 180° C. under a nitrogen atmosphere. To the mixture, 0.925 g of the reaction solution of InZnP quantum dot obtained in Production Example 2 was added, and the mixture was held at a temperature raised to 230° C. for 30 minutes, and then held at a temperature further raised to 300° C. for 60 minutes, so that an oleylamine/di-2-ethylhexylamine dispersion of InZnP/ZnSe quantum dots having InZnP in the core and ZnSe in the shell was obtained. After the resulting dispersion was cooled to 240° C., 0.423 g of dodecanethiol was injected and held for 90 minutes, so that an oleylamine/di-2-ethylhexylamine dispersion of multishell type quantum dot having InZnP in the core with ZnSe and ZnS layered in the shell was obtained.

After cooling the resulting dispersion to room temperature, 15 g of acetone was added thereto and stirred, and InZnP/ZnSe/ZnS quantum dots were collected as precipitates by centrifugation. The collected InZnP/ZnSe/ZnS quantum dots were suspended in 0.866 g of toluene to obtain a toluene dispersion of InZnP/ZnSe/ZnS quantum dots. To the dispersion, 15 g of acetone was further added and stirred, and InZnP/ZnSe/ZnS quantum dots were collected as precipitates by centrifugation. The collected InZnP/ZnSe/ZnS quantum dots were suspended in 0.7 g of octane to obtain an octane dispersion of purified InZnP/ZnSe/ZnS quantum dots. In Table 1, the measurement results of the emission properties of the resulting dispersion are shown. Further, the measurement results of emission spectrum of the resulting dispersion is shown in FIG. 3.

### Example 4

In a 10-mL reaction vessel, 0.1885 g of zinc oleate, 0.102 g of zinc chloride, 0.112 g of trioctylphosphine selenide, 0.332 g of trioctylphosphine, 1.304 g of oleylamine and 0.410 g of dibenzylamine were mixed, heated to 120° C. while stirring under reduced pressure, and degassed for 30 minutes. After degassing, the pressure was returned to atmospheric pressure with nitrogen gas, and the temperature was raised to 180° C. under a nitrogen atmosphere. To the mixture, 0.925 g of the reaction solution of InZnP quantum dot obtained in Production Example 2 was added, and the mixture was held at a temperature raised to 230° C. for 30 minutes, and then held at a temperature further raised to 300° C. for 60 minutes, so that an oleylamine/dibenzylamine dispersion of InZnP/ZnSe quantum dots having InZnP in the core and ZnSe in the shell was obtained. After the resulting dispersion was cooled to 240° C., 0.423 g of dodecanethiol was injected and held for 90 minutes, so that an oleylamine/dibenzylamine dispersion of multishell type quantum dot having InZnP in the core with ZnSe and ZnS layered in the shell was obtained.

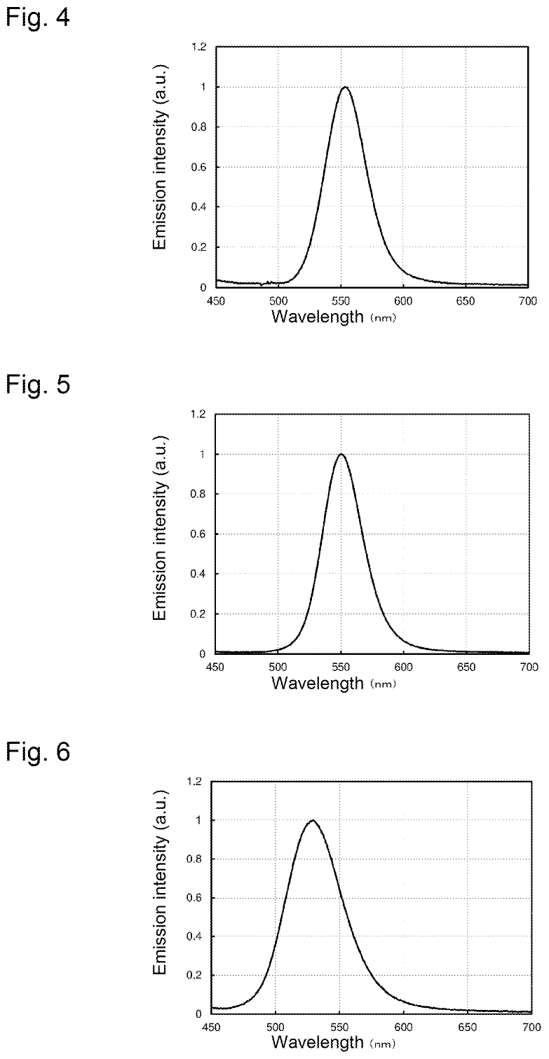

After cooling the resulting dispersion to room temperature, 15 g of acetone was added thereto and stirred, and InZnP/ZnSe/ZnS quantum dots were collected as precipitates by centrifugation. The collected InZnP/ZnSe/ZnS quantum dots were suspended in 0.866 g of toluene to obtain a toluene dispersion of InZnP/ZnSe/ZnS quantum dots. To the dispersion, 15 g of acetone was further added and stirred, and InZnP/ZnSe/ZnS quantum dots were collected as precipitates by centrifugation. The collected InZnP/ZnSe/ZnS quantum dots were suspended in 0.7 g of octane to obtain an octane dispersion of purified InZnP/ZnSe/ZnS quantum dots. In Table 1, the measurement results of the emission properties of the resulting dispersion are shown. Further, the measurement results of emission spectrum of the resulting dispersion is shown in FIG. 4.

### Example 5

In a 10-mL reaction vessel, 0.1885 g of zinc oleate, 0.102 g of zinc chloride, 0.112 g of trioctylphosphine selenide, 0.332 g of trioctylphosphine, 0.650 g of oleylamine, 0.820 g of dibenzylamine and 0.316 g of 1-octadecene were mixed, heated to 120° C. while stirring under reduced pressure, and degassed for 30 minutes. After degassing, the pressure was returned to atmospheric pressure with nitrogen gas, and the temperature was raised to 180° C. under a nitrogen atmosphere. To the mixture, 0.925 g of the reaction solution of InZnP quantum dot obtained in Production Example 2 was added, and the mixture was held at a temperature raised to 230° C. for 30 minutes, and then held at a temperature further raised to 300° C. for 60 minutes, so that an oleylamine/dibenzylamine/1-octadecene dispersion of InZnP/ZnSe quantum dots having InZnP in the core and ZnSe in the shell was obtained. After the resulting dispersion was cooled to 240° C., 0.423 g of dodecanethiol was injected and held for 90 minutes, so that an oleylamine/dibenzylamine/1-octadecene dispersion of multishell type quantum dot having InZnP in the core with ZnSe and ZnS layered in the shell was obtained.

After cooling the resulting dispersion to room temperature, 15 g of acetone was added thereto and stirred, and InZnP/ZnSe/ZnS quantum dots were collected as precipitates by centrifugation. The collected InZnP/ZnSe/ZnS quantum dots were suspended in 0.866 g of toluene to obtain a toluene dispersion of InZnP/ZnSe/ZnS quantum dots. To the dispersion, 15 g of acetone was further added and stirred, and InZnP/ZnSe/ZnS quantum dots were collected as precipitates by centrifugation. The collected InZnP/ZnSe/ZnS quantum dots were suspended in 0.7 g of octane to obtain an octane dispersion of purified InZnP/ZnSe/ZnS quantum dots. In Table 1, the measurement results of the emission properties of the resulting dispersion are shown. Further, the measurement results of emission spectrum of the resulting dispersion is shown in FIG. 5.

### Comparative Example 1

In a 10-mL reaction vessel, 0.1885 g of zinc oleate, 0.102 g of zinc chloride, 0.112 g of trioctylphosphine selenide, 0.332 g of trioctylphosphine, and 1.578 g of 1-octadecene were mixed, heated to 120° C. while stirring under reduced pressure, and degassed for 30 minutes. After degassing, the pressure was returned to atmospheric pressure with nitrogen gas, and the temperature was raised to 180° C. under a nitrogen atmosphere. To the mixture, 0.925 g of the reaction solution containing InZnP quantum dot synthesized in Production Example 2 was added, and the mixture was held at a temperature raised to 230° C. for 30 minutes, and then held at a temperature further raised to 300° C. for 60 minutes, so that 1-octadecene dispersion of InZnP/ZnSe quantum dots having InZnP in the core and ZnSe in the shell was obtained. After the resulting dispersion was cooled to 240° C., 0.423 g of dodecanethiol was injected and held for 90 minutes, so that a 1-octadecene dispersion of multishell type quantum dot having InZnP in the core with ZnSe and ZnS layered in the shell was obtained.

After cooling the resulting dispersion to room temperature, 15 g of acetone was added thereto and stirred, and InZnP/ZnSeS quantum dots were collected as precipitates by centrifugation. The collected InZnP/ZnSe/ZnS quantum dots were suspended in 0.866 g of toluene to obtain a toluene dispersion of InZnP/ZnSe/ZnS quantum dots. To the dispersion, 15 g of acetone was further added and stirred, and InZnP/ZnSe/ZnS quantum dots were collected as precipitates by centrifugation. The collected InZnP/ZnSe/ZnS quantum dots were suspended in 0.7 g of octane to obtain an octane dispersion of purified InZnP/ZnSe/ZnS quantum dots. In Table 1, the measurement results of the emission properties of the resulting dispersion are shown. Further, the measurement results of emission spectrum of the resulting dispersion is shown in FIG. 6.

### Comparative Example 2

In a 10-mL reaction vessel, 0.1885 g of zinc oleate, 0.102 g of zinc chloride, 0.112 g of trioctylphosphine selenide, 0.332 g of trioctylphosphine, and 1.626 g of oleylamine were mixed, heated to 120° C. while stirring under reduced pressure, and degassed for 30 minutes. After degassing, the pressure was returned to atmospheric pressure with nitrogen gas, and the temperature was raised to 180° C. under a nitrogen atmosphere. To the mixture, 0.925 g of the reaction solution containing InZnP quantum dot synthesized in Production Example 2 was added, and the mixture was held at a temperature raised to 230° C. for 30 minutes, and then held at a temperature further raised to 300° C. for 60 minutes, so that an oleylamine dispersion of InZnP/ZnSe quantum dots having InZnP in the core and ZnSe in the shell was obtained. After the resulting dispersion was cooled to 240° C., 0.423 g of dodecanethiol was injected and held for 90 minutes, so that an oleylamine dispersion of multishell type quantum dot having InZnP in the core with ZnSe and ZnS layered in the shell was obtained.

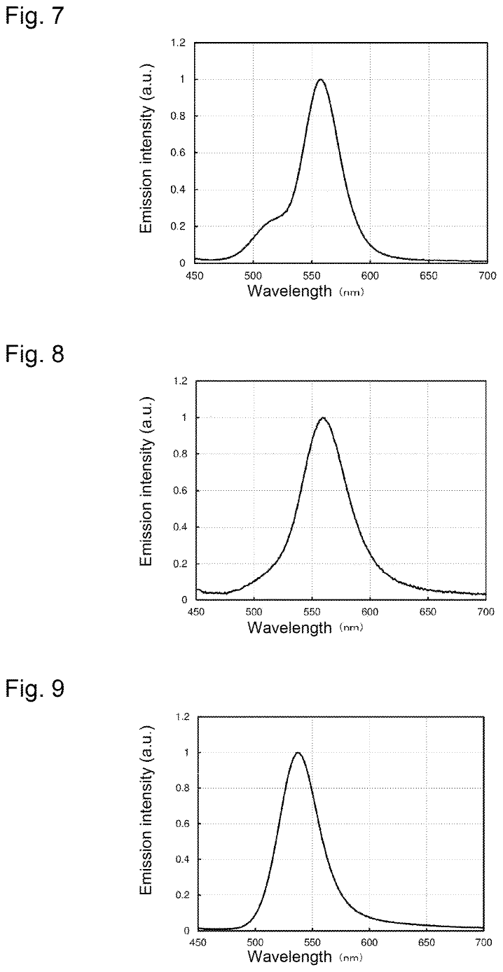

After cooling the resulting dispersion to room temperature, 15 g of acetone was added thereto and stirred, and InZnP/ZnSe/ZnS quantum dots were collected as precipitates by centrifugation. The collected InZnP/ZnSe/ZnS quantum dots were suspended in 0.866 g of toluene to obtain a toluene dispersion of InZnP/ZnSe/ZnS quantum dots. To the dispersion, 15 g of acetone was further added and stirred, and InZnP/ZnSe/ZnS quantum dots were collected as precipitates by centrifugation. The collected InZnP/ZnSe/ZnS quantum dots were suspended in 0.7 g of octane to obtain an octane dispersion of purified InZnP/ZnSe/ZnS quantum dots. In Table 1, the measurement results of the emission properties of the resulting dispersion are shown. Further, the measurement results of emission spectrum of the resulting dispersion is shown in FIG. 7.

### Comparative Example 3

In a 10-mL reaction vessel, 0.1885 g of zinc oleate, 0.102 g of zinc chloride, 0.112 g of trioctylphosphine selenide, 0.332 g of trioctylphosphine, and 1.599 g of dioctylamine were mixed, heated to 120° C. while stirring under reduced pressure, and degassed for 30 minutes. After degassing, the pressure was returned to atmospheric pressure with nitrogen gas, and the temperature was raised to 180° C. under a nitrogen atmosphere. To the mixture, 0.925 g of the reaction solution containing InZnP quantum dot synthesized in Production Example 2 was added, and the mixture was held at a temperature raised to 230° C. for 30 minutes, and then held at a temperature further raised to 300° C. for 60 minutes, so that a dioctylamine dispersion of InZnP/ZnSe quantum dots having InZnP in the core and ZnSe in the shell was obtained. After the resulting dispersion was cooled to 240° C., 0.423 g of dodecanethiol was injected and held for 90 minutes, so that a dioctylamine dispersion of multishell type quantum dot having InZnP in the core with ZnSe and ZnS layered in the shell was obtained.

After cooling the resulting dispersion to room temperature, 15 g of acetone was added thereto and stirred, and InZnP/ZnSe/ZnS quantum dots were collected as precipitates by centrifugation. The collected InZnP/ZnSe/ZnS quantum dots were suspended in 0.866 g of toluene to obtain a toluene dispersion of InZnP/ZnSe/ZnS quantum dots. To the dispersion, 15 g of acetone was further added and stirred, and InZnP/ZnSe/ZnS quantum dots were collected as precipitates by centrifugation. The collected InZnP/ZnSe/ZnS quantum dots were suspended in 0.7 g of octane to obtain an octane dispersion of purified InZnP/ZnSe/ZnS quantum dots. In Table 1, the measurement results of the emission properties of the resulting dispersion are shown. Further, the measurement results of emission spectrum of the resulting dispersion is shown in FIG. 8.

### Comparative Example 4

In a 10-mL reaction vessel, 0.1885 g of zinc oleate, 0.102 g of zinc chloride, 0.112 g of trioctylphosphine selenide, 0.332 g of trioctylphosphine, and 1.618 g of trioctylamine were mixed, heated to 120° C. while stirring under reduced pressure, and degassed for 30 minutes. After degassing, the pressure was returned to atmospheric pressure with nitrogen gas, and the temperature was raised to 180° C. under a nitrogen atmosphere. To the mixture, 0.925 g of the reaction solution containing InZnP quantum dot synthesized in Production Example 2 was added, and the mixture was held at a temperature raised to 230° C. for 30 minutes, and then held at a temperature further raised to 300° C. for 60 minutes, so that trioctylamine dispersion of InZnP/ZnSe quantum dots having InZnP in the core and ZnSe in the shell was obtained. After the resulting dispersion was cooled to 240° C., 0.423 g of dodecanethiol was injected and held for 90 minutes, so that a trioctylamine dispersion of multishell type quantum dot having InZnP in the core with ZnSe and ZnS layered in the shell was obtained.

After cooling the resulting dispersion to room temperature, 15 g of acetone was added thereto and stirred, and InZnP/ZnSeS quantum dots were collected as precipitates by centrifugation. The collected InZnP/ZnSe/ZnS quantum dots were suspended in 0.866 g of toluene to obtain a toluene dispersion of InZnP/ZnSe/ZnS quantum dots. To the dispersion, 15 g of acetone was further added and stirred, and InZnP/ZnSe/ZnS quantum dots were collected as precipitates by centrifugation. The collected InZnP/ZnSe/ZnS quantum dots were suspended in 0.7 g of octane to obtain an octane dispersion of purified InZnP/ZnSe/ZnS quantum dots. In Table 1, the measurement results of the emission properties of the resulting dispersion are shown. Further, the measurement results of emission spectrum of the resulting dispersion is shown in FIG. 9.

TABLE 1

| | | Full width | |
|---|---|---|---|
| | Maximum | at half | |
| | fluorescence | maximum | Quantum yield |
| | wavelength | (FWHM value) | (PLQY value) |
| Example 1 | 554 nm | 37.3 nm | 73% |
| Example 2 | 554 nm | 38.8 nm | 75% |
| Example 3 | 556 nm | 37.8 nm | 77% |
| Example 4 | 553 nm | 38.0 nm | 70% |
| Example 5 | 551 nm | 37.6 nm | 77% |
| Comparative Example 1 | 530 nm | 51.0 nm | 73% |
| Comparative Example 2 | 559 nm | 37.8 nm | 68% |
| Comparative Example 3 | 557 nm | 47.9 nm | 23% |
| Comparative Example 4 | 537 nm | 41.1 nm | 66% |

From the results in Table 1, it can be seen that although the FWHM values in Example 1 and Comparative Example 2 are equivalent, the PLQY value in Example 1 is higher or more excellent than that in Comparative Example 2. It can be seen that although the PLQY values in Example 1 and Comparative Example 1 are equivalent, the FWHM value in Example 1 is narrower or more excellent than that in Comparative Example 1. Both FWHM value and PLQY value in Comparative 3 are inferior to those in Example 1. Further, it can be seen that the emission spectra in Examples 1 to 5 are more excellent in symmetry with tails and shoulder suppressed in comparison with the emission spectra of Comparative Examples 1 to 4.

1. A method for producing a quantum dot having a core-shell structure, with a core composed of an InP-based quantum dot obtained by a reaction of at least a phosphorus source and an indium source, and a shell composed of a coating compound other than InP-based one, the method comprising
performing a reaction to coat the core with the coating compound in a solvent containing a plurality of amine derivatives.

2. The method for producing a quantum dot according to claim 1, wherein the amine derivatives are at least two or more selected from the group consisting of caprylamine, laurylamine, stearylamine, oleylamine, monoethylamine, monobutylamine, monodecylamine, monohexylamine, monooctylamine, monododecylamine, monohexadecylamine, benzylamine, diethylamine, dibutylamine, didecylamine, dihexylamine, dioctylamine, didodecylamine, dihexadecylamine, dibenzylamine, di-2-ethylhexylamine, triethylamine, tributylamine, tridecylamine, trihexylamine, trioctylamine, tridodecylamine, trihexadecylamine, and tribenzylamine.

3. The method for producing a quantum dot according to claim 1, wherein the reaction is performed in a solvent further containing a metal halide compound.

4. The method for producing a quantum dot according to claim 3, wherein the metal halide compound is at least one selected from the group consisting of zinc fluoride, zinc chloride, zinc bromide and zinc iodide.

5. The method for producing a quantum dot according to claim 1, wherein the coating compound is obtained from a reaction with at least a zinc source.

6. The method for producing a quantum dot according to claim 1, wherein the coating compound is ZnS, ZnSe, ZnSeS, ZnTe, ZnSeTe, ZnTeS, ZnO, ZnOS, ZnSeO or ZnTeO.

7. The method for producing a quantum dot according to claim 1, wherein the phosphorus source is a silylphosphine compound represented by the following general formula (1): 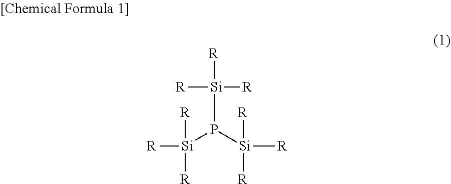
wherein each R is independently an alkyl group having 1 or more and 5 or less carbon atoms or an aryl group having 6 or more and 10 or less carbon atoms.

8. The method for producing a quantum dot according to claim 1, wherein the indium source is at least one selected from the group consisting of indium acetate, indium laurate, indium myristate, indium palmitate, indium stearate and indium oleate.

9. The method for producing a quantum dot according to claim 1, wherein the InP-based quantum dot is obtained by heating an InP quantum dot precursor at a temperature of 200° C. or more and 350° C. or less, wherein the InP quantum dot precursor is obtained from a reaction between a phosphorus source and an indium source at a temperature of 20° C. or more and 150° C. or less.

10. The method for producing a quantum dot according to claim 1, wherein the core is an InP-based quantum dot obtained by heating an InP quantum dot precursor together with a compound containing an elemental source M other than a phosphorus source and an indium source (M is at least one selected from the group consisting of Be, Mg, Ca, Mn, Cu, Zn, Cd, B, Al, Ga, N, As, Sb and Bi) at a temperature of 200° C. or more and 350° C. or less.
